(19) United States
(12) Patent Application Publication
(10) Pub. No.: US 2024/0243725 A1
(43) Pub. Date: Jul. 18, 2024

(54) ACOUSTIC RESONATOR BASED ON HIGH CRYSTALLINITY DOPED PIEZOELECTRIC THIN FILM, AND METHOD FOR PREPARING THE SAME

(71) Applicant: UNIVERSITY OF SCIENCE AND TECHNOLOGY OF CHINA, Hefei, Anhui (CN)

(72) Inventors: Chengjie ZUO, Hefei, Anhui (CN); Fuhong LIN, Hefei, Anhui (CN); Ziying WU, Hefei, Anhui (CN); Kai YANG, Hefei, Anhui (CN)

(21) Appl. No.: 18/562,534

(22) PCT Filed: Jun. 21, 2021
(86) PCT No.: PCT/CN2021/101172

§ 371 Date: Nov. 20, 2023

(51) Int. Cl. H03H 9/25; H03H 3/10; H03H 9/02

(52) U.S. Cl. CPC H03H 9/25; H03H 3/10; H03H 9/02834

(57) ABSTRACT

The present disclosure provides an acoustic resonator based on a high crystallinity doped piezoelectric thin film, including: a substrate; a seed layer arranged on the substrate, wherein the substrate and the seed layer form a Bragg reflection structure; a doped layer arranged on the seed layer; and a metal electrode arranged on the doped layer; wherein the seed layer is configured to increase a lattice matching degree between the doped layer and the substrate, and configured to reflect a sound wave emitted by the doped layer. The present disclosure further provides a method for preparing the acoustic resonator described above.

### CROSS-REFERENCE TO RELATED APPLICATION

This application is a Section 371 National Stage Application of International Application No. PCT/CN2021/101172, filed on Jun. 21, 2021, entitled “ACOUSTIC RESONATOR BASED ON HIGH CRYSTALLINITY DOPED PIEZOELECTRIC THIN FILM, AND METHOD FOR PREPARING THE SAME”, the content of which is hereby incorporated by reference in its entirety.

### TECHNICAL FIELD

The present disclosure relates to a field of preparation of a piezoelectric thin film resonator, and in particular, to an acoustic resonator based on a high crystallinity doped piezoelectric thin film and a method for preparing the same.

### BACKGROUND

In order to meet the application requirements of 5G and 6G, the market requires realization of a high crystallinity piezoelectric material and an acoustic resonator with high resonance frequency, high Q value (quality factor) and high electromechanical coupling coefficient (high bandwidth). However, the widely used surface acoustic wave (SAW) filters in the current market are difficult to meet the requirements of high frequency. In the traditional AlN film-based resonator preparation technology, if an element doping is not performed, the electromechanical coupling coefficient of the SAW modality (interdigital electrode modality) will be very low, and the bandwidth thereof cannot be used for 5G or 6G, while if an element doping is performed, a highly doped film with a high crystallinity cannot be obtained by using the traditional magnetron sputtering technology for growth on a silicon substrate. In the relevant researches, IHP SAW (super interdigital electrode modality) is prepared with lithium niobate or lithium tantalate single crystal film, and the prepared resonator has a relatively high electromechanical coupling coefficient. However, at present, a film growth manner with high quality and high crystallinity has not been found, and it can only be realized by Layer Transfer or in grinding manner. In this way, the cost is very high, and the film consistency is difficult to control. In the relevant researches, some scholars have prepared piezoelectric resonators operating at 2.3 GHz on silicon substrates based on Al_{0.77}Sc_{0.23}N (scandium doped aluminum nitride) thin films, but the electromechanical coupling coefficient (k²) thereof is only 1.03%, which cannot meet the design requirements of 4G or 5G high bandwidth filters.

### SUMMARY

In view of this, in order to obtain an acoustic resonator with a high electromechanical coupling coefficient, according to the present disclosure, there is provided an acoustic resonator based on a high crystallinity doped piezoelectric thin film and a method for preparing the same.

According to the present application, there is provided an acoustic resonator based on a high crystallinity doped piezoelectric thin film, the acoustic resonator including: a substrate; a seed layer arranged on the substrate, wherein the substrate and the seed layer form a Bragg reflection structure; a doped layer arranged on the seed layer; and a metal electrode arranged on the doped layer; wherein the seed layer is configured to increase a lattice matching degree between the doped layer and the substrate, and configured to reflect a sound wave emitted by the doped layer.

In some embodiments, the seed layer includes one or more layers, and a material of each layer includes one of: aluminum nitride, silicon dioxide, gallium nitride, silicon carbide, zinc oxide, lithium niobate, and lithium tantalate.

In some embodiments, the seed layer includes a plurality of groups of stacked layers, each group of stacked layers including at least N layers, where N≥2; different groups of stacked layers include the same number of layers; and a material of an i-th layer in different groups of stacked layers is the same, where 1≤i≤N.

In some embodiments, the doped layer includes an etched region and an unetched region thereon, and the etched region is a groove.

In some embodiments, the metal electrode is arranged on the unetched region of the doped layer.

In some embodiments, the metal electrode is arranged on the groove of the doped layer.

In some embodiments, the doped layer is a piezoelectric material containing a doped element.

In some embodiments, the doping layer is Al₁₋ₓScₓN, where a value range of x is between 0.05 and 0.8.

In some embodiments, a forming manner of the seed layer and the doped layer includes one of the following: a layer transfer method, a magnetron sputtering method, an epitaxial growth method, and a metal organic chemical vapor deposition method.

In some embodiments, a depth of the etched region of the doped layer is 10 to 500 nm.

In some embodiments, a normalized ratio of the depth of the etched region of the doped layer to a thickness of the unetched region of the doped layer is between 0 and 1.

In some embodiments, the metal electrode includes one of aluminum, gold, molybdenum, platinum, tungsten, or an alloy consisting of at least two of aluminum, gold, molybdenum, platinum, and tungsten.

In some embodiments, a thickness of the metal electrode is 10 to 2000 nm.

In some embodiments, the above acoustic resonator further includes a temperature compensation layer arranged on the metal electrode.

According to the present disclosure, there is further provided a method for preparing the above acoustic resonator, the method including: providing a substrate; forming a seed layer on the substrate, wherein the substrate and the seed layer form a Bragg reflection structure; forming a doped layer on the seed layer, wherein the seed layer is configured to increase a lattice matching degree between the doped layer and the substrate, and configured to reflect a sound wave emitted by the doped layer; and forming a metal electrode on the doped layer.

### BRIEF DESCRIPTION OF THE DRAWINGS

FIG. 1 is a schematic structural diagram of an acoustic resonator according to the present disclosure.

FIG. 2 is a schematic structural diagram of the acoustic resonator according to the embodiments of the present disclosure.

FIG. 3 is a finite element simulation result of the acoustic resonator according to the embodiments of the present disclosure.

FIGS. 4(a) and 4(b) are variation curves of electromechanical coupling coefficients and sound velocities with thicknesses of different metal electrodes of the acoustic resonator according to the embodiments of the present disclosure in a two-dimensional cross-section modality.

FIG. 5 is a schematic structural diagram of an acoustic resonator provided according to the embodiments of the present disclosure.

FIGS. 6(a) and 6(b) are variation curves of electromechanical coupling coefficients and sound velocities with etching depths of a doped layer of the acoustic resonator according to the embodiments of the present disclosure in a Rayleigh wave modality and a two-dimensional cross-section modality.

FIG. 7 is a schematic structural diagram of a temperature compensation layer formed on an acoustic resonator according to the embodiments of the present disclosure.

FIG. 8 is a schematic structural diagram of an acoustic resonator according to the embodiments of the present disclosure.

FIG. 9 is a schematic structural diagram of a temperature compensation layer formed on an acoustic resonator according to the embodiments of the present disclosure.

### DESCRIPTION OF REFERENCE SIGNS

1—Substrate; 2—Seed layer; 3—Doped layer; 4—Metal electrode; 5—Reflecting grating; 6—Temperature compensation layer; d-Depth of an etching region of a doped layer; h-Thickness of an unetched region of a doped layer

### DETAILED DESCRIPTION OF EMBODIMENTS

In order to make the objectives, technical solutions and advantages of the present disclosure clearer, the present disclosure will be further described in detail below in combination with specific embodiments and accompanying drawings.

According to the present disclosure, there is provided an acoustic resonator based on a high crystallinity doped piezoelectric thin film and a method for preparing the same, so as to greatly improve the electromechanical coupling coefficient of the obtained acoustic resonator.

As a substrate and a seed layer have different acoustic characteristics (acoustic impedances) from a doped layer, the substrate and the seed layer form a Bragg reflection structure, and the seed layer reflects a sound wave emitted by the doped layer, so that the sound wave energy is limited in the doped layer, and the acoustic wave resonator may excite a resonance modality with a high electromechanical coupling coefficient.

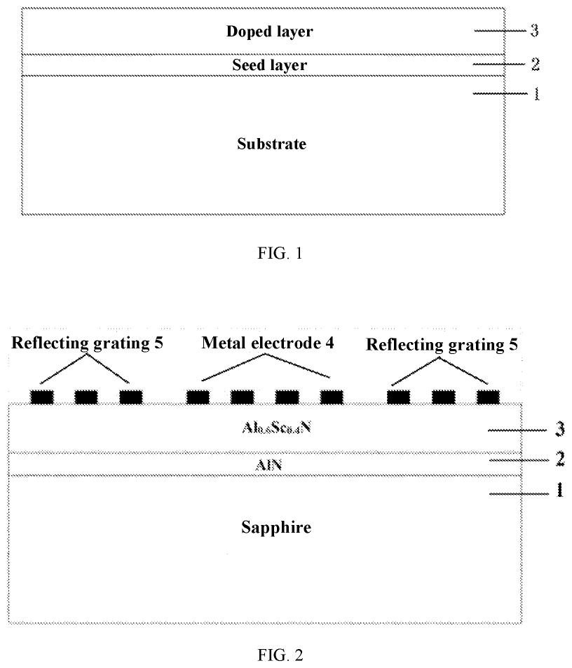

FIG. 1 is a schematic structural diagram of an acoustic resonator according to the present disclosure. As shown in FIG. 1, according to the present disclosure, there is provided an acoustic resonator based on a high crystallinity doped piezoelectric film. The acoustic resonator includes: a substrate 1; a seed layer 2 arranged on a substrate 1, wherein the substrate 1 and the seed layer 2 form a Bragg reflection structure; a doped layer 3 arranged on the seed layer 2; and a metal electrode 4 (see FIG. 2) arranged on the doped layer 3; wherein the seed layer 2 is configured to increase a lattice matching degree between the doped layer 3 and the substrate 1, and configured to reflect a sound wave emitted by the doped layer 3.

According to the embodiments of the present disclosure, the substrate 1 may include one of: sapphire (Al₂O₃), gallium nitride (GaN), silicon carbide (SiC), and silicon (Si).

According to the embodiments of the present disclosure, the seed layer 2 is a material that may increase the lattice matching degree between the doped layer 3 and the substrate 1, and may reflect the sound wave emitted by the doped layer 3.

According to the embodiments of the present disclosure, the seed layer 2 includes one or more layers, and a material of each layer may include one of the following: aluminum nitride, silicon dioxide, gallium nitride, silicon carbide, zinc oxide, lithium niobate, and lithium tantalate.

According to the embodiments of the present disclosure, the seed layer 2 may include a plurality of groups of stacked layers, each group of stacked layers includes at least N layers, where N≥2; different groups of stacked layers include a same layer number; and a material of an i-th layer in the different groups of stacked layers is the same, where 1≤i≤N.

According to the embodiments of the present disclosure, a seed layer 2 is arranged between the substrate 1 and the doped layer 3, so that the lattice matching degree between the doped layer 3 and the substrate 1 may be increased. Meanwhile, the substrate 1 and the seed layer 2 form a Bragg reflection structure, and the seed layer 2 reflects the sound wave emitted by the doped layer 3, so that the sound energy is limited in the doped layer 3, a Rayleigh wave modality with a higher electromechanical coupling coefficient may be excited, and a two-dimensional cross-section modality with a higher electromechanical coupling coefficient may be excited at a higher resonance frequency.

According to the embodiments of the present disclosure, the doped layer 3 is a piezoelectric material containing a doped element.

According to the embodiments of the present disclosure, the doped layer 3 may be Al₁₋ₓScₓN, wherein a value range of x may be between 0.05 and 0.8, for example, x may be 0.05, 0.1, 0.3, 0.6, and 0.8.

According to the embodiments of the present disclosure, the substrate 1 may be sapphire, the doped layer 3 may be Al₁₋ₓScₓN, and AlN is arranged between the sapphire and the Al₁₋ₓScₓN, so that when Al₁₋ₓScₓN is doped at a concentration of more than 40%, the FWHM (half peak width) may be less than 0.1°.

According to the embodiments of the present disclosure, the forming manner of the seed layer 1 and the doped layer 3 includes one of the following: a layer transfer method, a magnetron sputtering method, an epitaxial growth method, and a metal organic chemical vapor deposition method.

According to the embodiments of the present disclosure, the doped layer 3 includes an etched region and an unetched region, and the etched region is a groove.

According to the embodiments of the present disclosure, the metal electrode 4 is arranged on the unetched region of the doped layer 3.

According to the embodiments of the present disclosure, the metal electrode 4 is arranged on the groove of the doped layer 3.

According to the embodiments of the present disclosure, a depth d of the etched region of the doped layer 3 is 10 to 500 nm, for example, it may be 10 nm, 100 nm, 200 nm, 300 nm, and 500 nm.

According to the embodiments of the present disclosure, a normalized ratio of the depth d of the etched region of the doped layer 3 to a thickness h of the unetched region of the doped layer 3 is between 0 and 1, for example, it may be 0.2, 0.4, 0.6, 0.8, and 1.

According to the embodiments of the present disclosure, the metal electrode 4 includes one of aluminum (Al), gold (Au), molybdenum (Mo), platinum (Pt), tungsten (W), or an alloy consisting of at least two of aluminum, gold, molybdenum, platinum, and tungsten.

According to the embodiments of the present disclosure, the thickness of the metal electrode 4 is 10 to 2000 nm, for example, it may be 10 nm, 100 nm, 500 nm, 1000 nm, 2000 nm.

According to the embodiments of the present disclosure, the above acoustic resonator further includes a temperature compensation layer 6 arranged on the metal electrode 4.

According to the embodiments of the present disclosure, a material of the temperature compensation layer 6 may be silica.

According to the present disclosure, there is further provided a method for preparing the above acoustic resonator. The method includes: providing a substrate 1; forming a seed layer 2 on the substrate 1, wherein the substrate 1 and the seed layer 2 form a Bragg reflection structure; forming a doped layer 3 on the seed layer 2, wherein the seed layer 2 is configured to increase a lattice matching degree between the doped layer 3 and the substrate 1, and configured to reflect a sound wave emitted by the doped layer 3; etching the doped layer 3 to form an etched region of the doped layer 3 and an unetched region of the doped layer 3; forming a metal electrode 4 on the unetched region of the doped layer 3; or, forming a metal electrode 4 on the etched region of the doped layer; and forming a temperature compensation layer 6 on the metal electrode 4.

FIG. 2 is a schematic structural diagram of the acoustic resonator according to the embodiments of the present disclosure.

As shown in FIG. 2, the substrate 1 is sapphire, the seed layer 2 is AlN, and the doped layer 3 is Al_{0.6}Sc_{0.4}N. The metal electrode 4 and a reflecting grating 5 are formed on the doped layer 3.

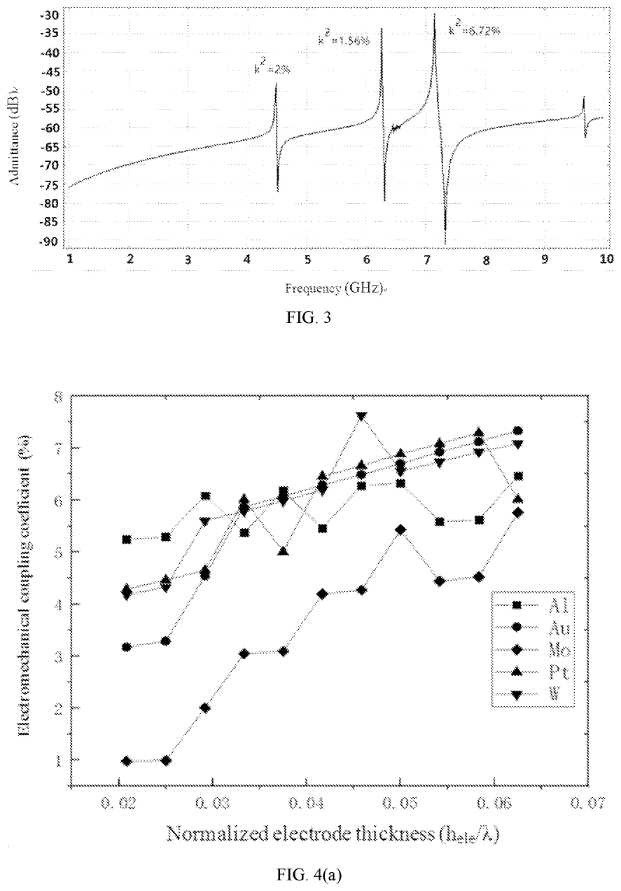

FIG. 3 is a finite element simulation result of the acoustic resonator according to the embodiments of the present disclosure.

As shown in FIG. 3, when the resonance frequency is 4.2 GHz, the excited resonance modality is Rayleigh wave modality, the electromechanical coupling coefficient reaches 2%, the vibration is mainly concentrated on the film surface, and the generated sound wave propagates along the surface, which is a sound surface wave. When the resonance frequency reaches 6.7 GHz, the excited resonance modality is a two-dimensional cross-section modality (XMR), and the electromechanical coupling coefficient reaches 6.72%.

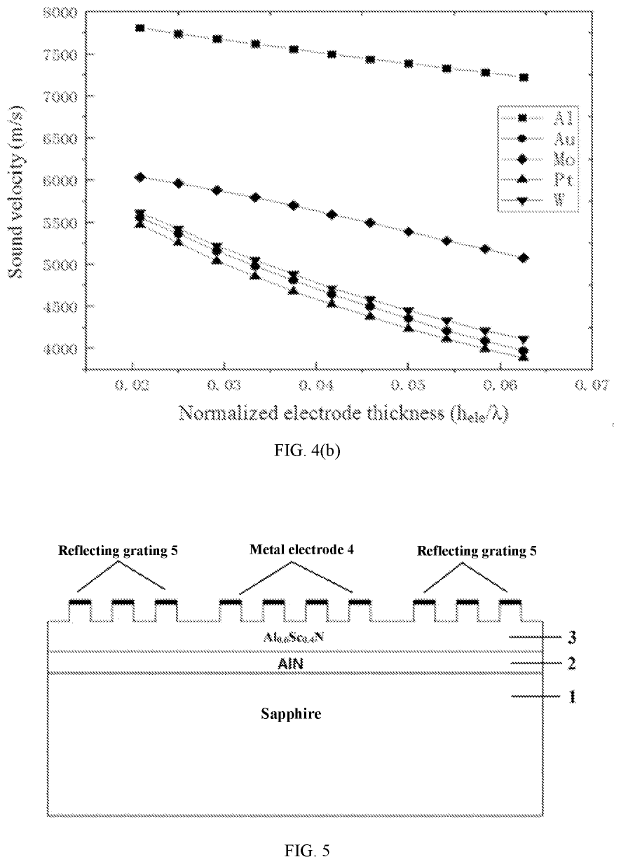

FIGS. 4(a) and 4(b) are variation curves of electromechanical coupling coefficients and sound velocities with thicknesses of different metal electrodes of the acoustic resonator according to the embodiments of the present disclosure in a two-dimensional cross-section modality.

As shown in FIGS. 4 (a) and 4 (b), as the thickness of the metal electrode 4 increases, the electromechanical coupling coefficient in the two-dimensional cross-section modality increases gradually, while the sound velocity decreases gradually due to the mass load effect. When the metal electrode 4 is tungsten and the normalized thickness is 0.045, the maximum electromechanical coupling coefficient k² in the two-dimensional cross-section modality (XMR) may be obtained as 7.6%, wherein the normalized thickness is the ratio of the thickness of the metal electrode to the wavelength of the sound wave.

FIG. 5 is a schematic structural diagram of an acoustic resonator provided according to the embodiments of the present disclosure. As shown in FIG. 5, the substrate 1 is sapphire, the seed layer 2 is AlN, and the doped layer 3 is Al_{0.6}Sc_{0.4}N. The doped layer 3 is etched to form an etched region and an unetched region of the doped layer 3. The metal electrode 4 is deposited in the unetched region of the doped layer 3 to form a mixed resonance modality of a quasi-surface acoustic wave and a quasi-body acoustic wave. The surface acoustic wave is a sound wave excited by a surface electrode on a film surface and propagates along the surface, and the body acoustic wave (BAW) is a sound wave that more energy is concentrated in a piezoelectric column after etching for a certain depth. BAW dominates the resonance and may be coupled with a surface acoustic wave excited by an upper electrode. The mixing and superposition of the two kinds of sound waves may increase the effective electromechanical coupling coefficient of a device.

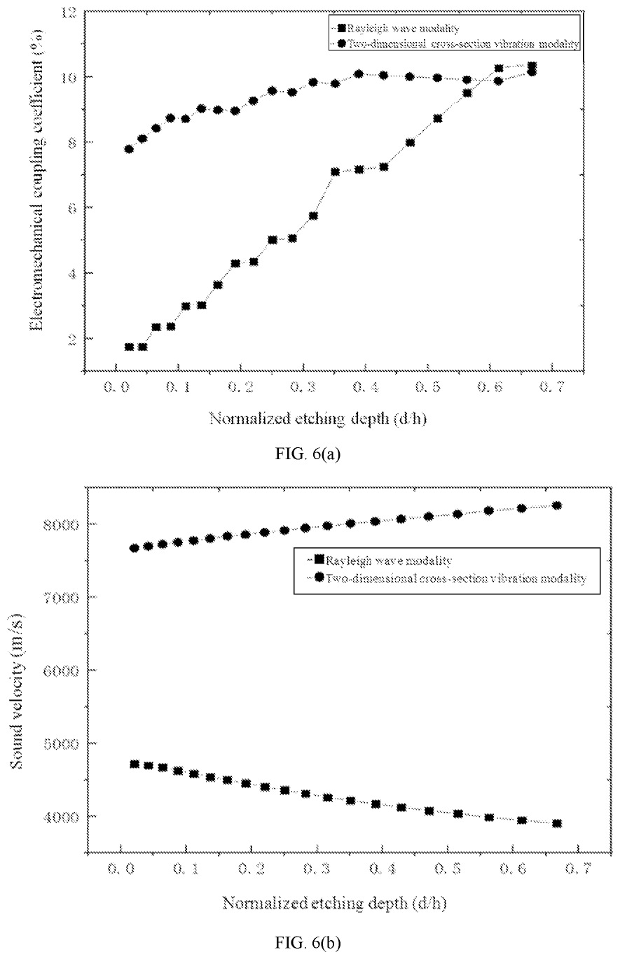

FIGS. 6(a) and 6(b) are variation curves of electromechanical coupling coefficients and sound velocities with etching depths of a doped layer of the acoustic resonator according to the embodiments of the present disclosure in a Rayleigh wave modality and a two-dimensional cross-section modality.

As shown in FIGS. 6 (a) and 6 (b), as the etching depth d of the doped layer 3 increases, the effective electromechanical coupling coefficient of the Rayleigh wave modality increases gradually and the sound velocity decreases gradually. As the etching depth d of the doped layer 3 increases, the effective electromechanical coupling coefficient of the two-dimensional cross-section modality remains above 8% and increases slightly, and the sound velocity increases gradually.

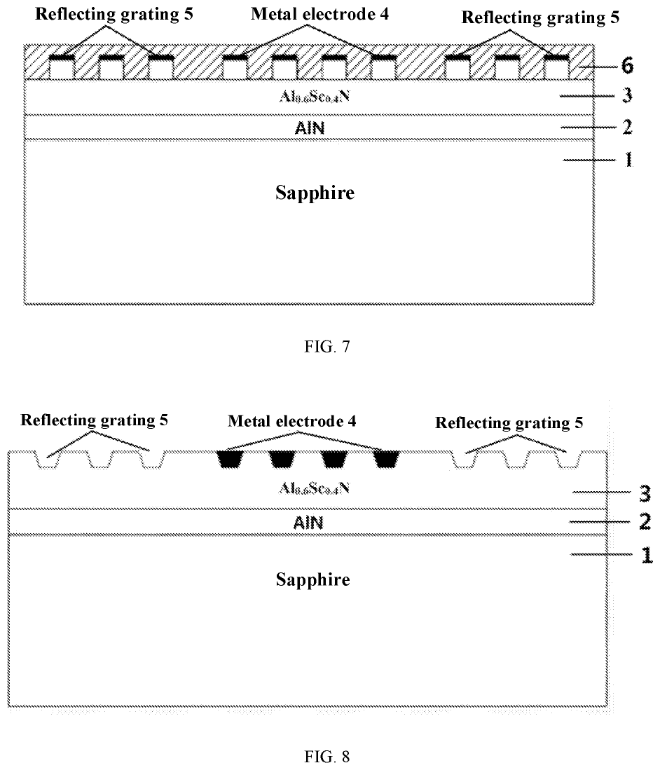

FIG. 7 is a schematic structural diagram of a temperature compensation layer formed on an acoustic resonator according to the embodiments of the present disclosure. As shown in FIG. 7, silicon dioxide is deposited on the metal electrode of the resonator in the mixed resonance modality of the quasi-surface acoustic wave and the quasi-body acoustic wave for temperature compensation, thereby improving the frequency stability of the resonator.

FIG. 8 is a schematic structural diagram of an acoustic resonator according to the embodiments of the present disclosure.

As shown in FIG. 8, the substrate 1 is sapphire, the seed layer 2 is AlN, and the doped layer 3 is Al_{0.6}Sc_{0.4}N. The doped layer 3 is etched to form an etched region and an unetched region of the doped layer 3. The metal electrode 4 is deposited in the etched region of the doped layer 3. The metal electrode 4 is deposited in a groove formed in the etched region of the doped layer, so that the obtained acoustic resonator may work in a high temperature environment. The reflecting grating 5 is set in a groove structure, thereby reducing generation of stray modalities.

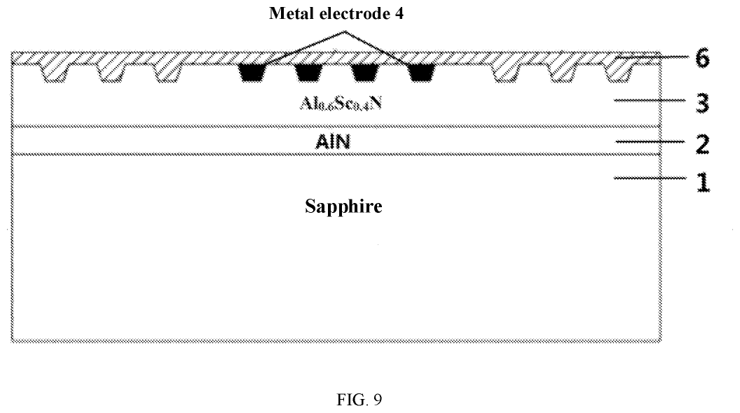

FIG. 9 is a schematic structural diagram of a temperature compensation layer formed on an acoustic resonator according to the embodiments of the present disclosure.

As shown in FIG. 9, a silicon dioxide layer is deposited on the upper surface of the acoustic resonator shown in FIG. 8 for temperature compensation, thereby improving the frequency stability of the acoustic resonator.

In the embodiments of the present disclosure, by arranging a seed layer between a substrate and a doped layer, a two-dimensional cross-section modality (XMR) with an electromechanical coupling coefficient up to 6.72% may be excited, and the two-dimensional cross-section modality (XMR) may work at 7.5 GHz, thereby meeting the requirements of high frequency and high bandwidth of 5G and 6G filters.

In the embodiments of the present disclosure, a doped layer is etched to form an etched region of the doped layer and an unetched region of the doped layer, and a metal electrode is arranged on the unetched region of the doped layer to form a mixed resonance modality of a quasi-surface acoustic wave and a quasi-body acoustic wave. The mixing and superposition of the two kinds of sound waves may increase the effective electromechanical coupling coefficient of a device. The metal electrode is arranged on a groove formed by the etched region of the doped layer, so that the obtained acoustic resonator may work in a high temperature environment. In addition, the frequency stability of the resonator may be improved by depositing a temperature compensation layer on the metal electrode.

The above specific embodiments further describe the objectives, technical solutions and beneficial effects of the present disclosure in detail. It should be understood that the above descriptions are only specific embodiments of the present disclosure and are not used to limit the present disclosure. Any modification, equivalent replacement, improvement, etc. within the spirits and principles of the present disclosure shall be included in the protection scope of the present disclosure.

1. An acoustic resonator based on a high crystallinity doped piezoelectric thin film, comprising:
a substrate;
a seed layer arranged on the substrate, wherein the substrate and the seed layer form a Bragg reflection structure;
a doped layer arranged on the seed layer; and
a metal electrode arranged on the doped layer;
wherein the seed layer is configured to increase a lattice matching degree between the doped layer and the substrate, and configured to reflect a sound wave emitted by the doped layer.

2. The acoustic resonator according to claim 1, wherein the seed layer comprises one or more layers, and a material of each layer comprises one of: aluminum nitride, silicon dioxide, gallium nitride, silicon carbide, zinc oxide, lithium niobate, and lithium tantalate.

3. The acoustic resonator according to claim 2, wherein the seed layer comprises a plurality of groups of stacked layers, each group of stacked layers comprising at least N layers, where N≥2;
different groups of stacked layers comprise the same number of layers; and
a material of an i-th layer in different groups of stacked layers is the same, where 1≤i≤N.

4. The acoustic resonator according to claim 1, wherein the doped layer comprises an etched region and an unetched region thereon, and the etched region is a groove.

5. The acoustic resonator according to claim 4, wherein the metal electrode is arranged on the unetched region of the doped layer.

6. The acoustic resonator according to claim 4, wherein the metal electrode is arranged on the groove of the doped layer.

7. The acoustic resonator according to claim 4, wherein the doped layer is a piezoelectric material containing a doped element;
a depth of the etched region of the doped layer is 10 to 500 nm; and
a normalized ratio of the depth of the etched region of the doped layer to a thickness of the unetched region of the doped layer is between 0 and 1.

8. The acoustic resonator according to claim 1, wherein the metal electrode comprises one of aluminum, gold, molybdenum, platinum, tungsten, or an alloy consisting of at least two of aluminum, gold, molybdenum, platinum, and tungsten; and
a thickness of the metal electrode is 10 to 2000 nm.

9. The acoustic resonator according to claim 1, further comprising a temperature compensation layer arranged on the metal electrode.

10. A method for preparing an acoustic resonator according to claim 1, comprising:
providing a substrate;
forming a seed layer on the substrate, wherein the substrate and the seed layer form a Bragg reflection structure;
forming a doped layer on the seed layer, wherein the seed layer is configured to increase a lattice matching degree between the doped layer and the substrate, and configured to reflect a sound wave emitted by the doped layer; and
forming a metal electrode on the doped layer.
